(19) United States
(12) Patent Application Publication
(10) Pub. No.: US 2025/0133858 A1
(43) Pub. Date: Apr. 24, 2025

(54) SEMICONDUCTOR DEVICE AND METHOD FOR MANUFACTURING THE SAME

(71) Applicant: SK hynix Inc., Icheon-si (KR)

(72) Inventor: Young Jun KWON, Icheon-si (KR)

(21) Appl. No.: 18/620,999

(22) Filed: Mar. 28, 2024

(30) Foreign Application Priority Data
Oct. 23, 2023 (KR) 10-2023-0142173

(51) Int. Cl. H01L 27/146

(52) U.S. Cl. CPC H10F 39/811; H10F 39/024; H10F 39/8053; H10F 39/8063

(57) ABSTRACT

The present disclosure relates to a semiconductor device manufacturing method that includes: forming a first layer including a first substrate, a first plug formed in the first substrate, a photodiode, and a first wiring layer; forming a second layer including a second substrate, a second plug formed in the second substrate, and a second wiring layer; forming a third layer including a third substrate and a third wiring layer; bonding the first wiring layer of the first layer to the second wiring layer of the second layer; and bonding the second substrate of the second layer to the third wiring layer of the third layer.

### CROSS-REFERENCE TO RELATED APPLICATION(S)

This patent document claims the priority and benefits of Korean Patent Application No. 10-2023-0142173, filed on Oct. 23, 2023, which is incorporated by reference in its entirety as part of the disclosure of this patent document.

### TECHNICAL FIELD

Various embodiments of the disclosed technology relate to a semiconductor device and a method for manufacturing the same.

### BACKGROUND

With the high integration of a semiconductor device, a technology for a stacked semiconductor device is being developed, which integrates required circuits or devices in two substrates of an upper substrate and a lower substrate respectively, and then bonds the two substrates, thereby reducing the area of a chip.

### SUMMARY

Some implementations of the disclosed technology provide a semiconductor device capable of minimizing thermal deformation such as warpage or shrink when stacking multiple layers, and a method for manufacturing the same.

In one aspect, a semiconductor device manufacturing method is disclosed. The manufacturing method includes: forming a first layer including a first substrate, a first plug formed in the first substrate, a photodiode, and a first wiring layer; forming a second layer including a second substrate, a second plug formed in the second substrate, and a second wiring layer; forming a third layer including a third substrate and a third wiring layer; bonding the first wiring layer of the first layer to the second wiring layer of the second layer; and bonding the second substrate of the second layer to the third wiring layer of the third layer.

In some implementations, the forming of the first layer may include: forming the first substrate; forming the photodiode and the first plug in the first substrate; forming the first wiring layer on the first substrate; and forming a first bonding pad in one region of the first wiring layer.

In some implementations, the forming of the second layer may include: forming the second substrate; forming the second plug in the second substrate; forming the second wiring layer on the second substrate; and forming a second bonding pad in one region of the second wiring layer.

In some implementations, the forming of the third layer may include: forming the third substrate; forming the third wiring layer on the third substrate; and forming a third bonding pad in one region of the third wiring layer.

In some implementations, the bonding of the first wiring layer of the first layer and the second wiring layer of the second layer may include bonding the first bonding pad of the first layer and the second bonding pad of the second layer.

In some implementations, the semiconductor device manufacturing method may further include, after the bonding of the first wiring layer of the first layer and the second wiring layer of the second layer: chemically mechanically polishing (CMP) the first substrate to a depth of a top of the first plug of the first layer; etching an upper portion of the first plug including the top of the first plug; forming a fourth bonding pad on the first plug; and forming a passivation layer on the first substrate.

In some implementations, the semiconductor device manufacturing method may further include, after the forming of the passivation layer: chemically mechanically polishing (CMP) the second substrate to a depth of a top of the second plug of the second layer; and etching an upper portion of the second plug including the top of the second plug.

In some implementations, the semiconductor device manufacturing method may further include, after the etching of the top of the second plug, forming a fifth bonding pad on the second plug.

In some implementations, the bonding of the second substrate of the second layer and the third wiring layer of the third layer may include bonding the fifth bonding pad of the second layer and the third bonding pad of the third layer.

In some implementations, the semiconductor device manufacturing method may further include, after the bonding of the second substrate of the second layer and the third wiring layer of the third layer, removing the passivation layer of the first layer.

In some implementations, the semiconductor device manufacturing method may further include, after the removing of the passivation layer of the first layer: forming a color filter over the photodiode of the first layer; and forming a microlens on the color filter.

In another aspect, a semiconductor device is provided to include: a first layer; a second layer disposed under the first layer; and a third layer disposed under the second layer, wherein the first layer comprises: a first wiring layer; a first substrate engaged to the first wiring layer; a first plug disposed in one region of the first substrate; and a first bonding pad disposed in one region of the first wiring layer, wherein the second layer comprises: a second substrate; a second wiring layer engaged to the second substrate; a second bonding pad disposed in one region of the second wiring layer and is in contact with the first bonding pad; and a second plug formed in one region of the second substrate, and wherein the third layer comprises: a third substrate; a third wiring layer disposed on the third substrate; and a third bonding pad disposed in one region of the third wiring layer.

In some implementations, the first layer may further include a fourth bonding pad disposed on the first plug.

In some implementations, the second layer may further include a fifth bonding pad that is disposed below the second plug and is in contact with the third bonding pad.

In some implementations, the first layer may further include: a photodiode disposed in one region of the first substrate; a color filter disposed over the photodiode; and a microlens disposed on the color filter.

In some implementations, the first layer further includes: a pixel array including pixels configured to provide an electrical signal in response to incident light.

In some implementations, the third layer further includes at least one of: an application processor configured to process data from the pixel array, or an artificial intelligence (AI) chip configured to perform an object recognition based on data from the pixel array.

In some implementations, the first wiring layer includes junction regions having a n-type region and a p-type region and gate electrodes including conductors.

In some implementations, each of the first substrate, the second substrate, the third substrate includes silicon-containing material.

### BRIEF DESCRIPTION OF THE DRAWINGS

FIG. 1 is a block diagram of an image sensing device that is a semiconductor device based on an implementation of the disclosed technology.

FIG. 2 shows a semiconductor device including a first layer, a second layer, and a third layer based on some implementations of the disclosed technology.

FIG. 3 illustrates an example process of providing a first layer based on some implementations of the disclosed technology.

FIG. 4 illustrates an example process of providing a second layer based on some implementations of the disclosed technology.

FIG. 5 illustrates an example process of providing a third t layer based on some implementations of the disclosed technology.

FIG. 6 illustrates an example process of bonding a first layer and a second layer based on some implementations of the disclosed technology.

FIG. 7 illustrates an example process of providing a fourth bonding pad and a passivation layer based on some implementations of the disclosed technology.

FIG. 8 illustrate an example process of etching a second substrate based on some implementations of the disclosed technology.

FIG. 9 illustrate an example process of providing a fifth bonding pad based on some implementations of the disclosed technology.

FIG. 10 illustrate an example process of bonding a second layer and a third layer based on some implementations of the disclosed technology.

FIG. 11 illustrates an example process of removing a passivation layer of a first layer based on some implementations of the disclosed technology.

FIGS. 12 illustrates an example process of forming a color filter based on some implementations of the disclosed technology.

### DETAILED DESCRIPTION

Features, and certain advantages in connection with specific implementations of the disclosed technology disclosed in this patent document are described by example embodiments with reference to the accompanying drawings.

It has been recognized that in a DRAM TSV process, a thermal deformation occurs, such as warpage or shrink when a subsequent thermal process is performed.

In some implementations of the disclosed technology, the plug is formed before bonding the upper layer and the lower layer, so that thermal deformation such as warpage or shrink by a subsequent thermal process can be prevented.

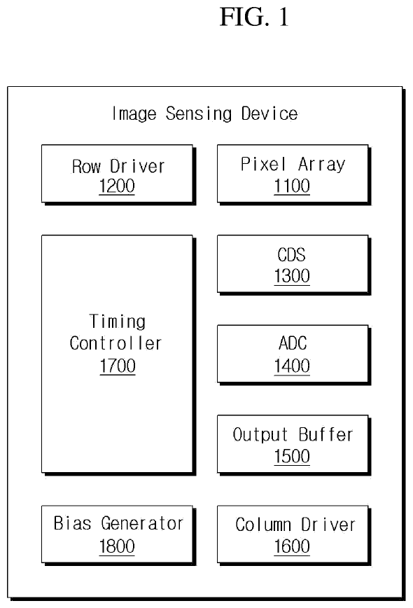

FIG. 1 is a block diagram of an image sensing device that is a semiconductor device according to an embodiment of the present disclosure.

Referring to FIG. 1, the image sensing device according to the embodiment includes a pixel array 1100, a row driver 1200, a correlated double sampler (CDS) 1300, and an analog-digital converter (ADC) 1400, an output buffer 1500, a column driver 1600, timing controller 1700, and a bias generator 1800. Here, each of the components of the image sensing device is merely an example, and at least some of the components may be added or omitted if necessary.

The pixel array 1100 may include a plurality of pixels arranged in a plurality of rows and a plurality of columns. In the embodiment, the plurality of pixels may be arranged in a two-dimensional pixel array including rows and columns. In another embodiment, a plurality of unit image pixels may be arranged in a three-dimensional pixel array. The plurality of pixels may convert an optical signal into an electrical signal on a pixel basis or on a pixel group basis, and pixels within the pixel group may share at least a specific internal circuit. The pixel array 1100 may receive a driving signal including a row selection signal, a pixel reset signal, and a transmission signal from the row driver 1200. A corresponding pixel of the pixel array 1100 may be activated to perform operations corresponding to the row selection signal, the pixel reset signal, and the transmission signal, by the driving signal.

The row driver 1200 may activate the pixel array 1100 such that specific operations are performed on pixels included in the corresponding row on the basis of commands and control signals provided by the timing controller 1700. In the embodiment, the row driver 1200 may select at least one pixel arranged in at least one row of the pixel array 1100. The row driver 1200 may generate the row selection signal in order to select at least one row among the plurality of rows. The row driver 1200 may sequentially enable the pixel reset signal and the transmission signal for pixels corresponding to at least one selected row. Accordingly, an analog reference signal and an image signal which are generated from each pixel of the selected row may be sequentially transmitted to the correlated double sampler 1300. Here, the reference signal may be an electrical signal which is provided to the correlated double sampler 1300 when a sensing node (e.g., floating diffusion node) of the pixel is reset, and the image signal may be an electrical signal which is provided to the correlated double sampler 1300 when photocharge generated by the pixel is accumulated in the sensing node. The reference signal indicating pixel-specific reset noise and the image signal indicating the intensity of incident light may be collectively referred to as a pixel signal.

A CMOS image sensor may use correlated double sampling in order to remove unwanted offset values in a pixel such as fixed pattern noise by sampling the pixel signal twice so as to remove the difference between two samples. For example, through the correlated double sampling, unwanted offset values are removed by comparing the pixel output voltages obtained before and after the photocharge generated by the incident light is accumulated in the sensing node, so that the pixel output voltage based only on the incident light can be measured. In the embodiment, the correlated double sampler 1300 may sequentially sample and hold the reference signal and the image signal provided to each of a plurality of column lines from the pixel array 1100. That is, the correlated double sampler 1300 may sample and hold the levels of the reference signal and the image signal corresponding to each column of the pixel array 1100.

The correlated double sampler 1300 may transmit the reference signal and the image signal of each column as a correlated double sampling signal to the ADC 1400 on the basis of the control signal from the timing controller 1700.

The ADC 1400 may convert and output the correlated double sampling signal for each column output from the correlated double sampler 1300 into a digital signal. In the embodiment, the ADC 1400 may be implemented as a ramp-compare type ADC. The ramp-compare type ADC may include a comparison circuit that compares a ramp signal that rises or falls over time with an analog pixel signal, and a counter that performs a counting operation until the ramp signal matches the analog pixel signal. In the embodiment, the ADC 1400 may convert and output the correlated double sampling signal generated by the correlated double sampler 1300 for each of the columns into a digital signal.

The ADC 1400 may include a plurality of column counters corresponding to the columns of the pixel array 1100 respectively. The columns of the pixel array 1100 are connected to the column counters, respectively, and image data may be generated by converting the correlated double sampling signals corresponding to the columns respectively into digital signals by using the column counters. According to another embodiment, the ADC 1400 may include one global counter and may convert the correlated double sampling signals corresponding to the columns respectively into digital signals by using a global code provided by the global counter.

The output buffer 1500 may temporarily hold and output each image data in units of column provided from the ADC 1400. The output buffer 1500 may temporarily store the image data output from the ADC 1400 on the basis of the control signal of the timing controller 1700. The output buffer 1500 may operate as an interface that compensates for differences in transmission (or processing) speed between the image sensing device and another device connected to the output buffer.

The column driver 1600 may select a column of the output buffer 1500 on the basis of the control signal of the timing controller 1700 and may control the image data temporarily stored in the selected column of the output buffer 1500 to be output sequentially. In the embodiment, the column driver 1600 may receive an address signal from the timing controller 1700, and the column driver 1600 may generate a column selection signal on the basis of the address signal and may select the column of the output buffer 1500, thereby controlling the image data to be output to the outside from the selected column of The output buffer 1500.

The timing controller 1700 may control at least one of the row driver 1200, the correlated double sampler 1300, the ADC 1400, the output buffer 1500, the column driver 1600, and the bias generator 1800.

The timing controller 1700 may provide a clock signal required for the operation of each component of the image sensing device, the control signal for timing control, the address signal for selecting rows or columns, and a signal for controlling a level of a bias voltage applied to the pixel array 1100, etc., to at least one of the row driver 1200, the correlated double sampler 1300, the ADC 1400, the output buffer 1500, the column driver 1600, and the bias generator 1800. According to the embodiment, the timing controller 1700 may include a logic control circuit, a phase lock loop (PLL) circuit, a timing control circuit, and a communication interface circuit, etc.

The bias generator 1800 may generate a bias voltage for suppressing dark current which is generated in the pixel of the pixel array 1100 and may supply the bias voltage to the pixel array 1100.

The bias voltage may be determined during a wafer probe test of the image sensing device and may be stored in one-time programmable memory (OTP). For example, the bias voltage has a value capable of minimizing unnecessary power consumption without degrading the performance of the image sensing device and of maximizing an effect of suppressing the dark current. The value of the bias voltage can be experimentally determined.

The bias generator 1800 may generate a voltage corresponding to the bias voltage stored in the OTP memory. According to the embodiment, the OTP memory may be included in the image sensing device, and in particular may be included in the bias generator 1800.

According to the embodiment, the bias voltage may include a plurality of values.

For example, the plurality of values may correspond to a plurality of operation modes of the image sensing device, respectively. The dark currents generated at low and high illuminances may be different from each other, and the bias voltage supplied by the bias generator 1800 in order to effectively suppress the dark current in each environment may vary depending on the mode.

Alternatively, the plurality of values may correspond to a plurality of areas of the pixel array 1100, respectively. The dark currents generated according to the position of the pixel on the pixel array 1100 may be different from each other, and the bias voltage supplied by the bias generator 1800 in order to effectively suppress the dark current regardless of the position of the pixel may vary depending on the area.

In the example, the bias voltage may be a negative voltage with a negative sign. However, the bias voltage can have a different value, e.g., a positive voltage, without being limited to the negative voltage.

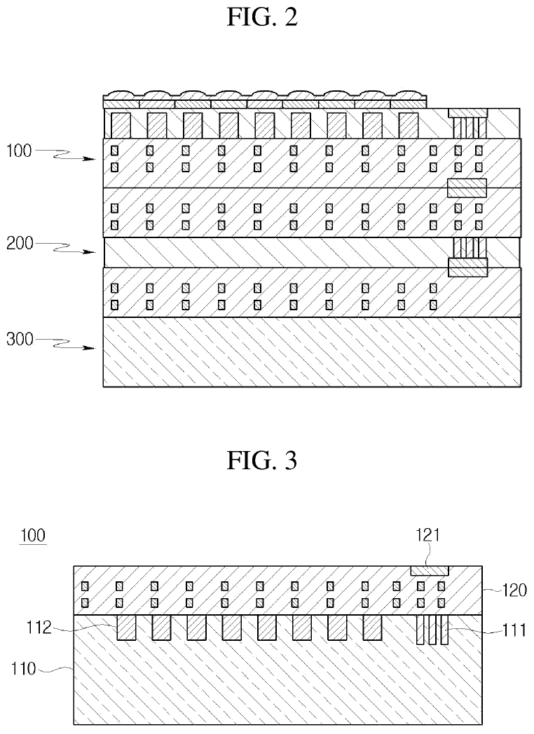

FIGS. 2 to 12 are views illustrating a semiconductor device manufacturing method.

Referring to FIGS. 2 to 12, a semiconductor device manufacturing method according to an embodiment includes forming a first layer 100 including a first substrate 110, a first plug 111 and a photodiode 112 which are formed in the first substrate 110, and a first wiring layer 120, forming a second layer 200 including a second substrate 210, a second plug 211 formed in the second substrate 210, and a second wiring layer 220, forming a third layer 300 including a third substrate 310 and a third wiring layer 320, bonding the first layer 100 and the second layer 200, and bonding the second layer 200 and the third layer 300. The photodiode 112 is described as one example of the photoelectric conversion element which is configured to convert the incident light into electrical charges. In some implementation, the photoelectric conversion element can be as a phototransistor, a photogate, or a combination thereof, etc.

FIGS. 3-5 illustrate the processes providing each of the first layer 100, the second layer 200, the third layer 300, respectively. In an example, the first layer 100 may include the pixel array including pixels configured to provide an electrical signal in response to incident light.

In an example, the second layer 200 may include logic circuits such as the row driver, the correlated double sampler, the analog-digital converter, the output buffer, the column driver, the timing controllers, and the bias generator, etc. The logic circuits are configured to provide various signals to the pixels in the pixel array as discussed with reference to FIG. 1.

The third layer 300 may include logic circuits such as an application processor (AP) and an artificial intelligence (AI) chip. For example, the third layer 300 may include at least one of the application processor or the AI chip. The application processor may process the data from the pixel array, run applications, and/or control the operations of the semiconductor device. The AI chip may be designed to perform AI tasks for various operations based on data from the pixel array, which includes, e.g., an object recognition, an image segmentation, an object tracking, etc.

Referring to FIG. 3, the forming the first layer 100 may include forming the first substrate 110, forming the photodiode 112 and the first plug 111 in the first substrate 110, forming the first wiring layer 120 on the first substrate 110, and forming a first bonding pad 121 in one region of the first wiring layer 120.

The first substrate 110 may include a semiconductor substrate. The first substrate 110 may be in a single crystal state and may include a silicon-containing material.

The first substrate 110 may be thinner through a thinning process. For example, the first substrate 110 may be a bulk silicon substrate thinned through the thinning process. In an example, the first substrate 110 may include P-type impurities.

In an example, the first plug 111 may be formed by using doped polysilicon (doped poly). In an example, the first plug 111 may be formed by removing poly through wet etching in order to reduce resistance and then by tungsten (W) or copper (Cu) gap-filling. For reducing resistance, a plurality of the first plugs 111 may be formed.

The first wiring layer 120 may include a plurality of junction regions (not shown), a plurality of gate electrodes (not shown), a plurality of metal wirings (not shown), and a plurality of vias (not shown).

The junction region (not shown) may include one of an n-type region including n-type impurity ions such as phosphorous (P) or arsenic (As) or a p-type region including p-type impurity ions such as boron (B).

The gate electrode (not shown) may include a conductor such as metal or doped poly-silicon.

The plurality of junction regions (not shown) may be used as source electrodes and/or drain electrodes of a logic transistor.

The plurality of metal wirings (not shown) and the plurality of vias (not shown) may include a conductor such as metal or doped poly-silicon. For example, the plurality of metal wirings (not shown) and the plurality of vias (not shown) may include a metal such as tungsten (W), copper (Cu), aluminum (AI), or titanium (Ti), a metal compound such as titanium nitride (TiN), or a metal silicide such as tungsten silicide (Wsi) or titanium silicide (TiSi).

An electrical signal may be transmitted between vertical layers through the plurality of vias (not shown).

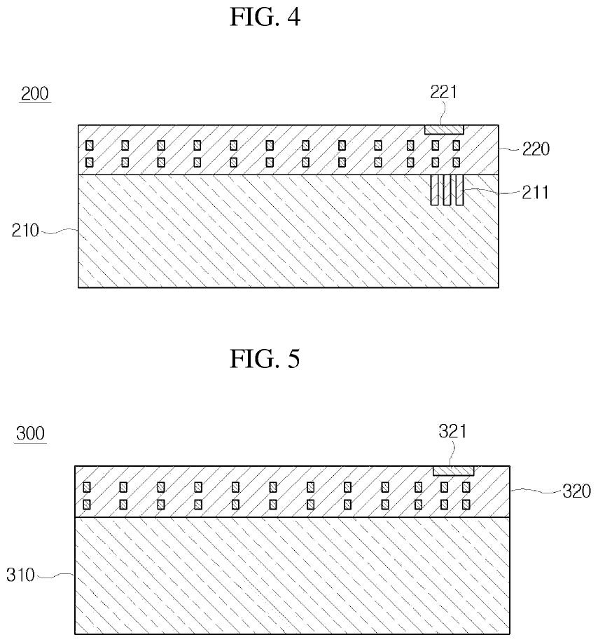

The first bonding pad 121 may include a metal or metal compound such as copper (Cu), titanium (Ti), or titanium nitride (TiN). Referring to FIG. 4, the forming the second layer 200 may include forming the second substrate 210, forming the second plug 211 in the second substrate 210, forming the second wiring layer 220 on the second substrate 210, and forming a second bonding pad 221 in one region of the second wiring layer 220.

The second substrate 210 may include a semiconductor substrate. The second substrate 210 may be in a single crystal state and may include a silicon-containing material.

The second substrate 210 may be thinner through a thinning process. For example, the second substrate 210 may be a bulk silicon substrate thinned through the thinning process. In an example, the second substrate 210 may include P-type impurities.

In an example, the second plug 211 may be formed by using doped poly. For example, the second plug 211 may be formed by removing poly through wet etching in order to reduce resistance and then by tungsten (W) or copper (Cu) gap-filling. For reducing resistance, a plurality of the second plugs 211 may be formed.

The second plug 211 is formed before bonding the second layer 200 and the third layer 300, so that thermal deformation such as warpage or shrink by a subsequent thermal process can be prevented.

The second wiring layer 220 may include a plurality of junction regions (not shown), a plurality of gate electrodes (not shown), a plurality of metal wirings (not shown), and a plurality of vias (not shown).

The junction region (not shown) may include one of an n-type region including n-type impurity ions such as phosphorous (P) or arsenic (As) or a p-type region including p-type impurity ions such as boron (B).

The gate electrode (not shown) may include a conductor such as metal or doped poly-silicon.

The plurality of junction regions (not shown) may be used as source electrodes and/or drain electrodes of a logic transistor.

Various logic transistors may be formed through the plurality of junction regions (not shown) and the gate electrodes (not shown). The plurality of logic transistors may form various logic circuits.

The plurality of metal wirings (not shown) and the plurality of vias (not shown) may include a conductor such as metal or doped poly-silicon. In an example, the plurality of metal wirings (not shown) and the plurality of vias (not shown) may include a metal such as tungsten (W), copper (Cu), aluminum (Al), or titanium (Ti), a metal compound such as titanium nitride (TiN), or a metal silicide such as tungsten silicide (Wsi) or titanium silicide (TiSi).

An electrical signal may be transmitted between vertical layers through the plurality of vias (not shown).

The second bonding pad 221 may include a metal or metal compound such as copper (Cu), titanium (Ti), or titanium nitride (TiN).

Referring to FIG. 5, the forming the third layer 300 may include forming the third substrate 310, forming the third wiring layer 320 on the third substrate 310, and forming a third bonding pad 321 in one region of the third wiring layer 320.

The third substrate 310 may include a semiconductor substrate. The third substrate 310 may be in a single crystal state and may include a silicon-containing material.

The third substrate 310 may be thinner through a thinning process. In an example, the third substrate 310 may be a bulk silicon substrate thinned through the thinning process. For example, the third substrate 310 may include P-type impurities.

The third wiring layer 320 may include a plurality of junction regions (not shown), a plurality of gate electrodes (not shown), a plurality of metal wirings (not shown), and a plurality of vias (not shown).

The junction region (not shown) may include one of an n-type region including n-type impurity ions such as phosphorous (P) or arsenic (As) or a p-type region including p- type impurity ions such as boron (B).

The gate electrode (not shown) may include a conductor such as metal or doped poly-silicon.

The plurality of junction regions (not shown) may be used as source electrodes and/or drain electrodes of a logic transistor.

Various logic transistors may be formed through the plurality of junction regions (not shown) and the gate electrodes (not shown). The plurality of logic transistors may form various logic circuits.

The plurality of metal wirings (not shown) and the plurality of vias (not shown) may include a conductor such as metal or doped poly-silicon. In an example, the plurality of metal wirings (not shown) and the plurality of vias (not shown) may include a metal such as tungsten (W), copper (Cu), aluminum (Al), or titanium (Ti), a metal compound such as titanium nitride (TiN), or a metal silicide such as tungsten silicide (Wsi) or titanium silicide (TiSi).

An electrical signal may be transmitted between vertical layers through the plurality of vias (not shown).

The third bonding pad 321 may include a metal or metal compound such as copper (Cu), titanium (Ti), or titanium nitride (TiN).

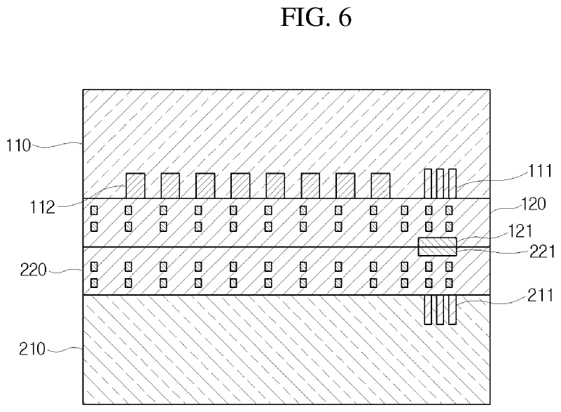

FIG. 6 illustrates an example process of bonding a first layer and a second layer based on implementations of the disclosed technology. Referring to FIG. 6, in the bonding of the first layer 100 and the second layer 200, the first wiring layer 120 of the first layer 100 and the second wiring layer 220 of the second layer 200 may be bonded to be in contact with each other, and the first bonding pad 121 of the first layer 100 and the second bonding pad 221 of the second layer 200 may be bonded to be in contact with each other.

The first layer 100 and the second layer 200 may be bonded through a hybrid bonding technology.

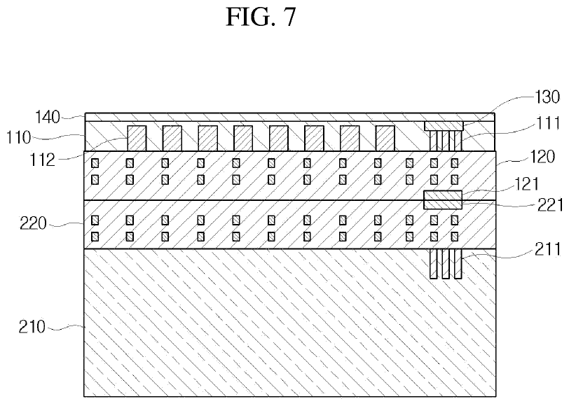

FIG. 7 illustrates an example process of providing a fourth bonding pad and a passivation layer based on some implementations of the disclosed technology. Referring to FIG. 7, the semiconductor device manufacturing method may include, after the bonding of the first layer 100 and the second layer 200, chemically mechanically polishing (CMP) the first substrate 110 to a depth of the top of the first plug 111 of the first layer 100, etching the upper portion of the first plug 111 including the top of the first plug 111, forming a fourth bonding pad 130 on the first plug 111 through copper (Cu) deposition, and forming a passivation layer 140 on the first substrate 110. For example, after the upper portion of the first plug 111 is etched, the fourth bonding pad 130 may be formed on the remaining portion of the first plug 111. The fourth bonding pad 130 may have a bottom surface that extends in a horizontal direction while contacting the remaining portion of the first plug 111 and a top surface that is flush with the surface of the first substrate 110.

After the first layer 100 and the second layer 200 are bonded, the fourth bonding pad 130 may be formed through the chemically mechanically polishing (CMP) to the depth of the top of the first plug 111 of the first layer 100, the etching the upper portion of the first plug 111 including the top of the first plug 111, and the copper (Cu) deposition.

After the fourth bonding pad 130 is formed, the passivation layer 140 may be formed on the photodiode 112 and the fourth bonding pad 130.

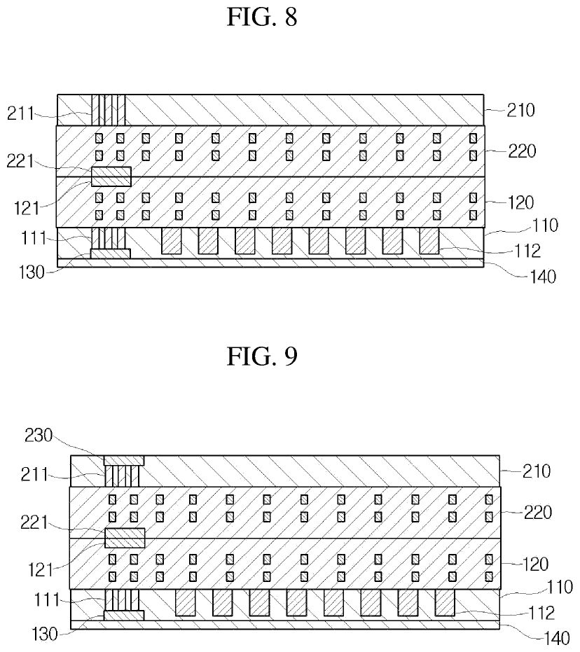

Referring to FIGS. 8 and 9, the semiconductor device manufacturing method may include, after the forming of the passivation layer 140, chemically mechanically polishing (CMP) the second substrate 210 to a depth of the top of the second plug 211 of the second layer 200, etching the upper portion of the second plug 211 including the top of the second plug 211, and forming a fifth bonding pad 230 on the second plug 211 through copper (Cu) deposition. For example, after the upper portion of the second plug 211 is etched, the fifth bonding pad 230 may be formed on the remaining portion of the second plug 211. The fifth bonding pad 230 may have a bottom surface that extends in a horizontal direction while contacting the remaining portion of the second plug 211 and a top surface that is flush with the surface of the second substrate 210.

After the passivation layer 140 is formed, the fifth bonding pad 230 may be formed through the chemically mechanically polishing (CMP) to the depth of the top of the second plug 211 of the second layer 200, the etching the upper portion of the second plug 211 including the top of the second plug 211, and the copper (Cu) deposition.

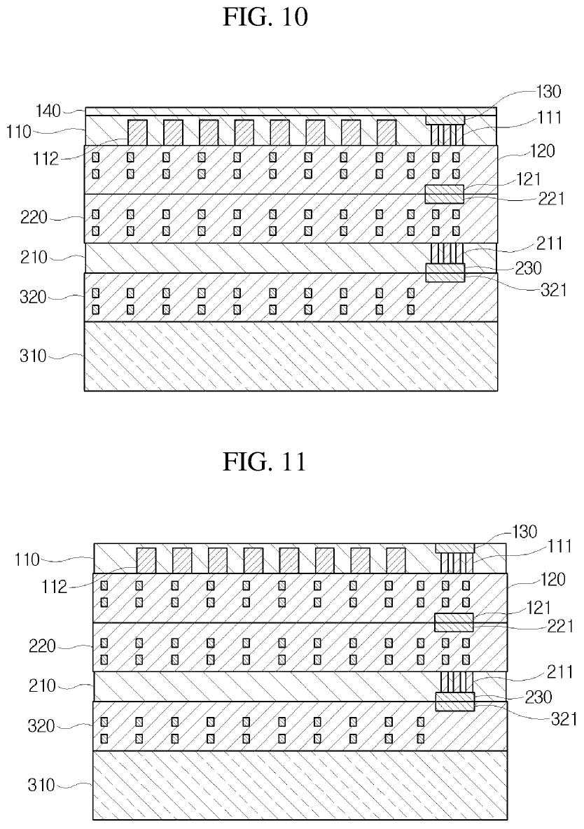

Referring to FIG. 10, the semiconductor device manufacturing method may include, after the forming of the fifth bonding pad 230, the bonding the second layer 200 and the third layer 300.

In the bonding of the second layer 200 and the third layer 300, the second substrate 210 of the second layer 200 and the third wiring layer 320 of the third layer 300 may be bonded to be in contact with teach other, and the fifth bonding pad 230 of the second layer 200 and the third bonding pad 321 of the third layer 300 may be bonded to be in contact with teach other.

The second layer 200 and the third layer 300 may be bonded through a hybrid bonding technology.

FIG. 11 illustrates an example process of removing a passivation layer of a first layer based on some implementations of the disclosed technology. Referring to FIG. 11, the semiconductor device manufacturing method may include, after the bonding of the second layer 200 and the third layer 300, removing the passivation layer 140 of the first layer 100.

After the second layer 200 and the third layer 300 are bonded, the passivation layer 140 may be removed through the chemically mechanically polishing (CMP).

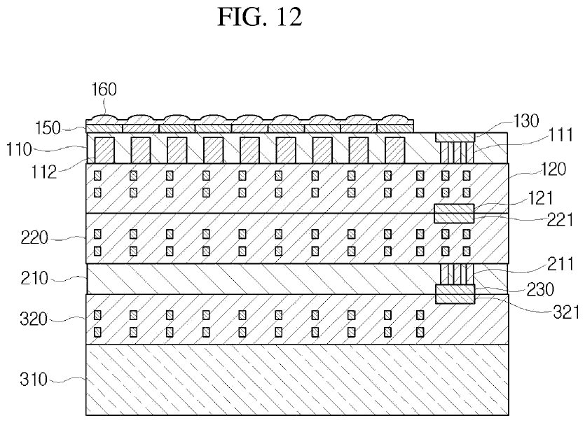

FIG. 12 illustrates an example process of forming a color filter based on some implementations of the disclosed technology. Referring to FIG. 12, the semiconductor device manufacturing method may include, after the removing of the passivation layer 140, forming a color filter 150 over the photodiode 112 of the first layer 100, and forming a microlens 160 on the color filter 150.

After the passivation layer 140 is removed, a pixel array including the color filter 150 and the microlens 160 may be formed.

After the first plug 111 is in advance formed in the first layer 100 where a pixel area is formed, the first plug 111 is exposed through the chemically mechanically polishing (CMP) during a back side illumination (BSI) process. Then, tungsten-polysilicon (W-Poly Si) bonding can be used to enable signal transmission between the upper and lower layers.

Referring to FIGS. 2 and 12, the semiconductor device according to the embodiment includes the first layer 100, the second layer 200 bonded under the first layer 100, and the third layer 300 bonded under the second layer 200.

The first layer 100 may include the first wiring layer 120, the first substrate 110 formed on the first wiring layer 120, the first plug 111 formed in one region of the first substrate 110, the first bonding pad 121 formed in one region of the first wiring layer 120, and the fourth bonding pad 130 formed on the first plug 111.

The first layer 100 may include the photodiode 112 formed in one region of the first substrate 110, the color filter 150 formed over the photodiode 112, and the microlens 160 formed on the color filter 150.

The second layer 200 may include the second substrate 210, the second wiring layer 220 formed on the second substrate 210, the second bonding pad 221 which is formed in one region of the second wiring layer 220 and is bonded to the first bonding pad 121, the second plug 211 formed in one region of the second substrate 210, and the fifth bonding pad 230 which is formed below the second plug 211 and is bonded to the third bonding pad 321.

The third layer 300 includes the third substrate 310, the third wiring layer 320 formed on the third substrate 310, and the third bonding pad 321 formed in one region of the third wiring layer 320.

Since the components of the first layer 100, the second layer 200, and the third layer 300 are the same as those described above, detailed descriptions thereof will be omitted.

While this patent document contains many specifics, these should not be construed as limitations on the scope of any subject matter or of what may be claimed, but rather as descriptions of features that may be specific to particular embodiments of particular techniques. Certain features that are described in this patent document in the context of separate embodiments can also be implemented in combination in a single embodiment. Conversely, various features that are described in the context of a single embodiment can also be implemented in multiple embodiments separately or in any suitable subcombination. Moreover, although features may be described above as acting in certain combinations and even initially claimed as such, one or more features from a claimed combination can in some cases be excised from the combination, and the claimed combination may be directed to a subcombination or variation of a subcombination.

Only a few implementations and examples of the disclosed technology are described and other implementations, enhancements and variations can be made based on what is described and illustrated in this patent document.

I/we claim:

1. A semiconductor device manufacturing method comprising:
forming a first layer including a first substrate, a first plug formed in the first substrate, a photodiode, and a first wiring layer;
forming a second layer including a second substrate, a second plug formed in the second substrate, and a second wiring layer;
forming a third layer including a third substrate and a third wiring layer;
bonding the first wiring layer of the first layer to the second wiring layer of the second layer; and
bonding the second substrate of the second layer to the third wiring layer of the third layer.

2. The semiconductor device manufacturing method of claim 1, wherein the forming of the first layer comprises:
forming the first substrate;
forming the photodiode and the first plug in the first substrate;
forming the first wiring layer on the first substrate; and
forming a first bonding pad in one region of the first wiring layer.

3. The semiconductor device manufacturing method of claim 2, wherein the forming of the second layer comprises:
forming the second substrate;
forming the second plug in the second substrate;
forming the second wiring layer on the second substrate; and
forming a second bonding pad in one region of the second wiring layer.

4. The semiconductor device manufacturing method of claim 3, wherein the forming of the third layer comprises:
forming the third substrate;
forming the third wiring layer on the third substrate; and
forming a third bonding pad in one region of the third wiring layer.

5. The semiconductor device manufacturing method of claim 4, wherein the bonding of the first wiring layer of the first layer and the second wiring layer of the second layer comprises bonding the first bonding pad of the first layer and the second bonding pad of the second layer.

6. The semiconductor device manufacturing method of claim 5, further comprising, after the bonding of the first wiring layer of the first layer and the second wiring layer of the second layer:
chemically mechanically polishing (CMP) the first substrate to a depth of a top of the first plug of the first layer;
etching an upper portion of the first plug including the top of the first plug;
forming a fourth bonding pad on the first plug; and
forming a passivation layer on the first substrate.

7. The semiconductor device manufacturing method of claim 6, further comprising, after the forming of the passivation layer:
chemically mechanically polishing (CMP) the second substrate to a depth of a top of the second plug of the second layer; and
etching an upper portion of the second plug including the top of the second plug.

8. The semiconductor device manufacturing method of claim 7, further comprising, after the etching of the top of the second plug, forming a fifth bonding pad on the second plug.

9. The semiconductor device manufacturing method of claim 8, wherein the bonding of the second substrate of the second layer and the third wiring layer of the third layer comprises bonding the fifth bonding pad of the second layer and the third bonding pad of the third layer.

10. The semiconductor device manufacturing method of claim 9, further comprising, after the bonding of the second substrate of the second layer and the third wiring layer of the third layer, removing the passivation layer of the first layer.

11. The semiconductor device manufacturing method of claim 10, further comprising, after the removing of the passivation layer of the first layer:
forming a color filter over the photodiode of the first layer; and
forming a microlens on the color filter.

12. A semiconductor device comprising:
a first layer;
a second layer disposed under the first layer; and
a third layer disposed under the second layer,
wherein the first layer comprises:
a first wiring layer;
a first substrate engaged to the first wiring layer;
a first plug disposed in one region of the first substrate; and
a first bonding pad disposed in one region of the first wiring layer,
wherein the second layer comprises:
a second substrate;
a second wiring layer engaged to the second substrate;
a second bonding pad disposed in one region of the second wiring layer and is in contact with the first bonding pad; and
a second plug formed in one region of the second substrate,
and wherein the third layer comprises:
a third substrate;
a third wiring layer disposed on the third substrate; and
a third bonding pad disposed in one region of the third wiring layer.

13. The semiconductor device of claim 12, wherein the first layer further comprises a fourth bonding pad disposed on the first plug.

14. The semiconductor device of claim 13, wherein the second layer further comprises a fifth bonding pad that is disposed below the second plug and is in contact with the third bonding pad.

15. The semiconductor device of claim 14, wherein the first layer further comprises:
a photodiode disposed in one region of the first substrate;
a color filter disposed over the photodiode; and
a microlens disposed on the color filter.
